(19) United States
(12) Patent Application Publication
(10) Pub. No.: US 2026/0026383 A1
(43) Pub. Date: Jan. 22, 2026

(54) SEMICONDUCTOR PACKAGE

(71) Applicant: LG INNOTEK CO., LTD., Seoul (KR)

(72) Inventor: Ho Dol YOO, Seoul (KR)

(73) Assignee: LG INNOTEK CO., LTD., Seoul (KR)

(21) Appl. No.: 18/993,113

(22) PCT Filed: Jul. 12, 2023
(86) PCT No.: PCT/KR2023/009957

§ 371 Date: Jan. 10, 2025

(30) Foreign Application Priority Data
Jul. 12, 2022 (KR) 10-2022-0085709

(51) Int. Cl. H01L 23/498; H01L 23/00; H01L 23/10; H01L 23/367; H01L 23/373; H01L 25/065

(52) U.S. Cl. CPC H01L 23/49894; H01L 23/10; H01L 24/16; H01L 24/32; H01L 24/33; H01L 24/73; H01L 23/3677; H01L 23/3735; H01L 25/0655; H01L 25/0657; H01L 2224/16145; H01L 2224/16227; H01L 2224/32137; H01L 2224/32145; H01L 2224/32225; H01L 2224/33181; H01L 2224/73204; H01L 2224/73253

(57) ABSTRACT

A semiconductor package according to an embodiment includes a substrate; a protective layer disposed on the substrate; a first adhesive member disposed on the protective layer and having an open loop shape along a circumferential direction of an upper surface of the protective layer; and a cover member disposed on the first adhesive member, wherein a lower surface of the cover member includes: a first lower surface that contacts the first adhesive member, and a second lower surface that does not contact the first adhesive member, and the protective layer includes a first opening that vertically overlaps the second lower surface of the cover member and does not vertically overlap the first adhesive member.

### TECHNICAL FIELD

An embodiment relates to a semiconductor package.

### BACKGROUND ART

As the performance of electrical/electronic products progresses, technologies for attaching a larger number of packages to a substrate of limited size are being proposed and studied. However, since a typical package is based on mounting a single semiconductor chip, there is a limit to obtaining the desired performance.

A typical package substrate has a form in which a processor package in which a processor chip is disposed and a memory package in which a memory chip is disposed are connected as one. This package substrate is manufactured by combining a processor chip and a memory chip into a single integrated package, thereby reducing a mounting area of the chip and enabling high-speed signal transmission through a short path.

Due to these advantages, the package substrate is widely used in mobile devices, etc.

Meanwhile, an area of the package has been expanding due to high specifications of electronic devices such as mobile devices and an adoption of HBM (High Bandwidth Memory).

In addition, as an area of the semiconductor package increases, there is a problem that the semiconductor package warps more. In addition, as the area of the semiconductor package increases, heat generation becomes more severe, and accordingly, there is a problem that the heat dissipation characteristics must be improved more.

Accordingly, conventional semiconductor packages employ a cover member (or lid) to improve bending characteristics and heat dissipation characteristics. The cover member includes a metal material with excellent heat conductivity.

The cover member is attached to an adhesive member applied on the package substrate. At this time, the adhesive member in a conventional semiconductor package is applied in a closed loop shape to a circumferential region of an upper surface of the package substrate. In addition, when the adhesive member is applied in a closed loop shape on the substrate, a physical reliability problem occurs in which gas is not discharged during a thermal process performed after an attachment of the cover member, or a semiconductor device mounted on the semiconductor package is separated from the package substrate due to gas that expands due to heat generated during the operation of the product, or the cover member is separated from the package substrate.

Meanwhile, in order to solve the above problem, the adhesive member is not applied to some regions of the circumferential region of the upper surface of the package substrate. That is, according to a prior art, the adhesive member is applied on the package substrate in an open loop shape. In addition, some regions where the adhesive member is not applied function as vent holes that discharge the gas.

However, when a width of some regions where the adhesive member is not applied on the package substrate increases, there is a problem in that an adhesive force between the package substrate and the cover member is deteriorated through the adhesive member.

In addition, when the width of some regions where the adhesive member is not applied on the package substrate is reduced, an area of the vent hole may not be sufficiently secured, and thus, a physical reliability problem may occur due to the gas not being easily discharged.

(Patent Document 1) KR 10-2017-0107596 A

### DISCLOSURE

### Technical Problem

The embodiment provides a semiconductor package having a novel structure.

In addition, the embodiment provides a semiconductor package having improved heat dissipation characteristics.

In addition, the embodiment provides a semiconductor package having improved adhesion between a package substrate and a cover member.

In addition, the embodiment provides a semiconductor package having improved gas discharge characteristics in a thermal process after an adhesive member application process.

In addition, the embodiment provides a semiconductor package capable of increasing an area of a vent hole while increasing an application area of the adhesive member.

In addition, the embodiment provides a semiconductor package capable of being slimmed down and miniaturized.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A semiconductor package according to an embodiment comprises a substrate; a protective layer disposed on the substrate; a first adhesive member disposed on the protective layer and having an open loop shape along a circumferential direction of an upper surface of the protective layer; and a cover member disposed on the first adhesive member, wherein a lower surface of the cover member includes: a first lower surface that contacts the first adhesive member, and a second lower surface that does not contact the first adhesive member, and the protective layer includes a first opening that vertically overlaps the second lower surface of the cover member and does not vertically overlap the first adhesive member.

In addition, at least a portion of the second lower surface of the cover member does not vertically overlap the first opening.

In addition, an upper surface of the protective layer includes a circumferential region adjacent to a circumference of the upper surface of the protective layer, and the first adhesive member is partially disposed in the circumferential region along the circumferential direction.

In addition, the first opening vertically overlaps a region of the circumferential region in which the first adhesive member is not disposed.

In addition, a width in the circumferential direction of the region in which the first adhesive member is not disposed is larger than a width in the circumferential direction of the first opening.

In addition, a plurality of first openings are provided to be spaced apart from each other along the circumferential direction, and the first adhesive member includes a plurality of first adhesive patterns disposed along the circumferential direction between the plurality of first openings.

In addition, the first opening is connected to an outer side surface of the protective layer.

In addition, the protective layer includes a recess concave from an upper surface of the protective layer toward a lower surface of the protective layer and vertically overlapping the first adhesive member, and the first adhesive member is disposed in the recess.

In addition, the recess is spaced apart from the outer side surface of the protective layer and connected to the first opening.

In addition, the substrate includes an insulating layer; and a first electrode layer disposed on the insulating layer, and the protective layer includes a second opening passing through upper and lower surfaces of the protective layer and vertically overlapping the first electrode layer.

In addition, the first opening does not vertically overlap with the first electrode layer.

In addition, the semiconductor package further comprises a first connection part disposed on the first electrode layer vertically overlapped with the second opening; and a semiconductor device disposed on the first connection part.

In addition, the cover member includes a side plate portion spaced apart from the semiconductor device and covering a side region of the semiconductor device; and an upper plate portion extended from the side plate portion and covering an upper region of the semiconductor device, and a lower surface of the cover member is a lower surface of the side plate portion.

In addition, the semiconductor package further comprises a second adhesive member disposed between an upper surface of the semiconductor device and a lower surface of the upper plate portion.

In addition, the semiconductor package further comprises a third adhesive member disposed on an upper surface of the upper plate portion; and a heat sink disposed on the third adhesive member.

In addition, the semiconductor package further comprises a molding member disposed on the substrate and molding the first connection part and a side surface of the semiconductor device.

In addition, the protective layer includes a solder resist.

### Advantageous Effects

The semiconductor package of the embodiment includes a substrate and a protective layer disposed on the substrate. In addition, the protective layer includes a first opening provided in a circumferential region of an upper surface of the protective layer and passing through the upper surface and the lower surface of the protective layer. In addition, the semiconductor package includes a first adhesive member disposed in the circumferential region of the upper surface of the protective layer and a cover member disposed on the first adhesive member.

At this time, the first adhesive member may be partially disposed in the circumferential region of the protective layer. Specifically, the first adhesive member may have an open loop shape along a circumferential direction of the upper surface of the protective layer.

Accordingly, the circumferential region includes a disposition region where the first adhesive member is disposed and a non-disposition region where the first adhesive member is not disposed. At this time, the non-disposition region vertically overlaps the first opening.

In other words, a lower surface of the cover member includes a first lower surface that contacts the first adhesive member and a second lower surface that does not contact the first adhesive member. In addition, the first opening vertically overlaps with the second lower surface of the cover member, but does not vertically overlap with the first adhesive member.

Accordingly, the embodiment can utilize not only the non-disposition region of the first adhesive member, but also a first opening of the protective layer connected to the non-disposition region as a vent hole. Therefore, the embodiment can easily discharge gas existing in a cavity space defined as an inner space of the cover member to an outside. Accordingly, the embodiment can solve physical reliability problems and electrical reliability problems caused by a presence of the gas in the cavity space. Therefore, the embodiment can further improve the product reliability of the semiconductor package.

Meanwhile, the protective layer of the embodiment includes a recess provided in a region where the first adhesive member is to be disposed while being connected to the first opening. In addition, the first adhesive member can be disposed in the recess. Through this, the embodiment can lower a height of the semiconductor package by a depth of the recess. Therefore, the embodiment can miniaturize the semiconductor package.

In addition, the embodiment allows a width of the non-disposition region of the first adhesive member to be greater than a width of the first opening. At this time, each of the width of the first opening and the width of the non-disposition region each mean a width in the circumferential direction of the upper surface of the protective layer. Accordingly, the embodiment can prevent the first adhesive member from overflowing into the first opening. Accordingly, the embodiment can further improve the product reliability of the semiconductor package. Furthermore, the embodiment provides a step between the non-disposition region and the first opening so that the gas generated in the cavity space can flow in a direction toward the first opening. Accordingly, the embodiment can further improve discharge characteristics of the gas.

### DESCRIPTION OF DRAWINGS

FIG. 1 is a cross-sectional view showing a semiconductor package according to a first embodiment.

FIG. 2 is a cross-sectional view showing a semiconductor package according to a second embodiment.

FIG. 3 is a cross-sectional view showing a semiconductor package according to a third embodiment.

FIG. 4 is a cross-sectional view showing a semiconductor package according to a fourth embodiment.

FIG. 5 is a plan view showing a first protective layer of a first embodiment.

FIG. 6 is a plan view showing a first protective layer of a second embodiment.

FIG. 7 is a plan view showing a first protective layer of a third embodiment.

FIG. 8 is a plan view showing a first protective layer of a fourth embodiment.

FIG. 9 is a drawing showing a state where a first adhesive member is disposed on a first protective layer of a first embodiment.

FIG. 10 is a drawing showing a state where a first adhesive member is disposed on a first protective layer of a second embodiment.

FIG. 11 is a cross-sectional view showing a semiconductor package according to a fifth embodiment.

FIG. 12 is a plan view showing a first protective layer of a semiconductor package of FIG. 11.

FIG. 13 is a drawing showing a state in which a first adhesive member is disposed on a first protective layer of FIG. 12.

FIGS. 14 to 23 are cross-sectional views for explaining a method for manufacturing a semiconductor package according to an embodiment in order of processes.

### BEST MODE

Hereinafter, embodiments of the present invention will be described in detail with reference to the accompanying drawings.

However, the spirit and scope of the present invention is not limited to a part of the embodiments described, and may be implemented in various other forms, and within the spirit and scope of the present invention, one or more of the elements of the embodiments may be selectively combined and redisposed.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art. In addition, the terms used in the embodiments of the present invention are for describing the embodiments and are not intended to limit the present invention.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present invention, the terms such as first, second, A, B, (a), and (b) may be used.

These terms are only used to distinguish the elements from other elements, and the terms are not limited to the essence, order, or order of the elements. In addition, when an element is described as being “connected”, or “coupled” to another element, it may include not only when the element is directly “connected” to, or “coupled” to other elements, but also when the element is “connected”, or “coupled” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements. Furthermore, when expressed as “on (over)” or “under (below)”, it may include not only the upper direction but also the lower direction based on one element.

### Electronic Device

Before describing the embodiment, an electronic device including a semiconductor package of the embodiment will be briefly described. The electronic device includes a main board (not shown). The main board can be physically and/or electrically connected to various components. For example, the main board can be connected to the semiconductor package of the embodiment. Various semiconductor devices can be mounted in the semiconductor package.

The semiconductor devices can include active devices and/or passive devices. The active devices can be semiconductor chips in the form of integrated circuits (ICs) in which hundreds to millions of devices are integrated into one chip. The semiconductor chips can be logic chips, memory chips, etc. The logic chips can be central processors (CPUs), graphics processors (GPUs), etc. For example, the logic chip may be an AP including at least one of a central processor (CPU), a graphics processor (GPU), a digital signal processor, an encryption processor, a microprocessor, a microcontroller, or an analog-to-digital converter, an application-specific IC (ASIC), or a chip set including a specific combination of the above.

The memory chip may be a stacked memory such as HBM. In addition, the memory chip may include a memory chip such as a volatile memory (e.g., DRAM), a non-volatile memory (e.g., ROM), a flash memory, etc.

Meanwhile, a product group to which the semiconductor package of the embodiment is applied may be any one of a CSP (Chip Scale Package), an FC-CSP (Flip Chip-Chip Scale Package), an FC-BGA (Flip Chip Ball Grid Array), a POP (Package On Package), and a SIP (System In Package), but is not limited thereto.

In addition, the electronic device may be a smart phone, a personal digital assistant, a digital video camera, a digital still camera, a network system, a computer, a monitor, a tablet, a laptop, a netbook, a television, a video game, a smart watch, an automotive, etc. However, the embodiment is not limited thereto, and it may be any other electronic device that processes data.

### Semiconductor Package

Hereinafter, a semiconductor package according to an embodiment will be described.

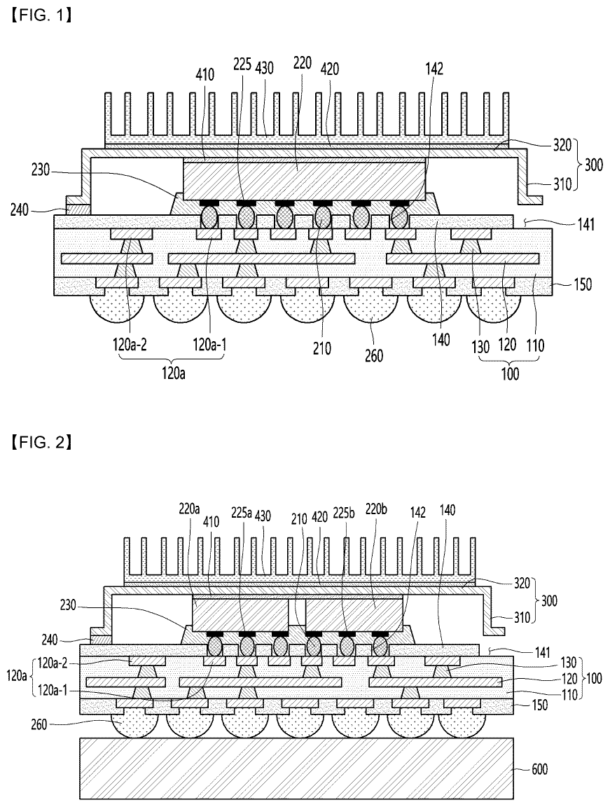

FIG. 1 is a cross-sectional view showing a semiconductor package according to the first embodiment.

Referring to FIG. 1, the semiconductor package includes a substrate 100.

In one embodiment, the substrate 100 may be a package substrate. For example, the substrate 100 may be a substrate disposed between a semiconductor device and a main board of an electronic device. For example, the substrate 100 may be a substrate disposed between an interposer on which a semiconductor device is mounted and the main board. At this time, the interposer may be an active interposer that also performs a semiconductor device function, or may be a passive interposer that only performs an electrical connection function.

In another embodiment, the substrate 100 may be an interposer. For example, the substrate 100 may be a substrate disposed between a package substrate 600 connected to a main board of an electronic device and a semiconductor device. This is illustrated in FIG. 2, and will be described below with reference to FIG. 2.

The substrate 100 includes an insulating layer 110, an electrode layer 120, and a through electrode 130.

The insulating layer 110 of the substrate 100 may have a layer structure of at least one layer or more. Preferably, the insulating layer 110 of the substrate 100 may have a multi-layer structure. Through this, the substrate 100 of the embodiment may efficiently electrically connect between the main board of the electronic device and the semiconductor device. At this time, the insulating layer 110 of the substrate 100 in FIG. 1 is illustrated as having a three-layer structure, but is not limited thereto. For example, the insulating layer 110 of the substrate 100 may have two or fewer layers, or may have four or more layers.

When the insulating layer 110 of the substrate 100 has a multi-layer structure, a plurality of insulating layers of the substrate 100 may include a same insulating material, but are not limited thereto. For example, at least one insulating layer among a plurality of insulating layers of the substrate 100 may include an insulating material different from another insulating layer.

The insulating layer 110 of the substrate 100 may be rigid or flexible. For example, the insulating layer 110 of the substrate 100 may include glass or plastic. For example, the insulating layer 110 of the substrate 100 may include chemically strengthened/semi-strengthened glass such as soda lime glass or aluminosilicate glass. For example, the insulating layer 110 of the substrate 100 may include a reinforced or flexible plastic such as polyimide (PI), polyethylene terephthalate (PET), propylene glycol (PPG), or polycarbonate (PC). For example, the insulating layer 110 of the substrate 100 may include sapphire. For example, the insulating layer 110 of the substrate 100 may include an optically isotropic film. For example, the insulating layer 110 of the substrate 100 may include COC (Cyclic Olefin Copolymer), COP (Cyclic Olefin Polymer), optically isotropic polycarbonate (PC), or optically isotropic polymethyl methacrylate (PMMA). For example, the insulating layer 110 of the substrate 100 may be formed of a material including an inorganic filler and an insulating resin. For example, the insulating layer 110 of the substrate 100 may have a structure in which an inorganic filler of silica or alumina is disposed in a thermosetting resin or a thermoplastic resin.

Specifically, in one embodiment, the insulating layer 100 of the substrate 100 may include a first insulating layer including reinforcing fibers, and a second insulating layer that is disposed on top and bottom of the first insulating layer and does not include reinforcing fibers. Therefore, the substrate 100 may be a core substrate.

In addition, in another embodiment, the insulating layer 100 of the substrate 100 may be composed only of an insulating layer that does not include reinforcing fibers. Therefore, the substrate 100 may be a coreless substrate.

In one embodiment, the insulating layer 110 of the substrate 100 may include an organic material that does not include a reinforcing member that has excellent processability, excellent rigidity, enables slimming of the substrate 100, and enables miniaturization of the electrode layer 120 of the substrate 100. The reinforcing member may also be referred to as a reinforcing fiber or glass fiber.

For example, the insulating layer 110 of the substrate 100 may use ABF (Ajinomoto Build-up Film), FR-4, BT (Bismaleimide Triazine), PID (Photo Imageable Dielectric resin), BT, etc.

At this time, if the insulating layer 110 of the substrate 100 is composed of ABF (Ajinomoto Build-up Film), the bending characteristics of the substrate 100 may be deteriorated.

Therefore, in another embodiment, the insulating layer 110 of the substrate 100 is composed of ABF (Ajinomoto Build-up Film), and at least one ABF among the plurality of insulating layers of the substrate 100 may include a reinforcing material capable of improving the bending characteristics.

For example, the insulating layer 110 of the substrate 100 includes a layer composed of a first ABF including a resin and a filler. In addition, the insulating layer 110 of the substrate 100 includes a layer composed of a second ABF further including a reinforcing material in the first ABF. At this time, the reinforcing material included in the second ABF may be glass fiber and may include a GCP (Glass Core Primer) material, but is not limited thereto.

Each layer of the insulating layer 110 of the substrate 100 may have a thickness in a range of 10 μm to 40 μm. Preferably, each layer of the insulating layer 110 of the substrate 100 may satisfy a thickness in a range of 15 μm to 35 μm. More preferably, each layer of the insulating layer 110 of the substrate 100 may satisfy a thickness in a range of 18 μm to 32 μm. If the thickness of each layer of the insulating layer 110 of the substrate 100 is less than 10 μm, the bending characteristics of the substrate 100 may deteriorate. In addition, if the thickness of each layer of the insulating layer 110 of the substrate 100 is less than 10 μm, the electrode layer 120 of the substrate 100 may not be stably protected, and thus the electrical reliability may deteriorate. In addition, if the thickness of each layer of the insulating layer 110 of the substrate 100 exceeds 40 μm, an overall thickness of the substrate 100 may increase, and accordingly, a thickness of the semiconductor package may increase.

In addition, if the thickness of each layer of the insulating layer 110 of the substrate 100 exceeds 40 μm, it may be difficult to miniaturize the electrode layer 120 of the substrate 100.

The thickness of each layer of the insulating layer 110 of the substrate 100 may correspond to a distance in a vertical direction of the substrate between the electrode layers disposed in different layers. That is, the thickness may mean a length in a direction from an upper surface to a lower surface of the substrate 100, or from the lower surface to the upper surface, and may mean a length in the vertical direction of the substrate. Here, the upper surface may mean a highest position along the vertical direction in each component, and a lower surface may mean the lowest position along the vertical direction in each component. In addition, the positions thereof may be referred to oppositely.

Meanwhile, the semiconductor package of the embodiment includes a first protective layer 140 disposed on the upper surface of the substrate 100. In addition, the semiconductor package includes a second protective layer 150 disposed on the lower surface of the substrate 100.

The insulating layer 110 of the substrate 100 may have a multi-layer structure. In addition, the upper surface of the insulating layer 110 described below may mean an upper surface of an uppermost layer among the insulating layers provided with a plurality of layers. In addition, the lower surface of the insulating layer 110 described below may mean a lower surface of a lowermost layer among the insulating layer 110 provided with a plurality of layers. At this time, when the first protective layer 140, which is a protective layer provided with a different material from a material constituting the insulating layer 110, is disposed on the upper surface of the insulating layer 110, an upper surface of the insulating layer 110 and a lower surface of the first protective layer 140 may be distinguished. In addition, when a second protective layer 150, which is a protective layer provided with a different material from the material constituting the insulating layer 110, is disposed on a lower surface of the insulating layer 110, the lower surface of the insulating layer 110 and the upper surface of the second protective layer 150 can be distinguished.

The substrate 100 includes an electrode layer 120. The electrode layer 120 can be disposed on a surface of the insulating layer 110 of the substrate 100. For example, when the insulating layer 110 of the substrate 100 has a three-layer structure, the electrode layer 120 can be disposed on surfaces of the three insulating layers, respectively.

At this time, one of the electrode layers 120 of the substrate 100 can have an ETS (Embedded Trace Substrate) structure. For example, the electrode layer disposed on an upper surface of the insulating layer 110 of the substrate 100 may have an ETS structure. Accordingly, at least a part of the electrode layer disposed on an uppermost side of the substrate 100 may be disposed in a recess (not shown) formed on the upper surface of the insulating layer 110. Accordingly, the ETS structure may also be referred to as a buried structure. The ETS structure is advantageous for miniaturization compared to an electrode layer having a general protruding structure. Accordingly, the embodiment enables miniaturization of the electrode layer disposed on the upper surface of the insulating layer 110 of the substrate 100 by having an ETS structure. That is, the electrode layer disposed on the upper surface of the insulating layer 110 includes electrodes connected to a semiconductor device or an external substrate. Accordingly, the embodiment enables formation of the electrodes corresponding to a size and a pitch of terminals provided in the semiconductor device. Through this, the embodiment can improve the circuit integration. In addition, the embodiment can minimize a transmission distance of a signal transmitted through the semiconductor device, thereby minimizing the signal transmission loss.

At this time, the first electrode pattern 120a-1 of the electrode layer 120 can include a protrusion that protrudes further toward the semiconductor device 220 than the upper surface of the first protective layer 140. The protrusion can be referred to as a bump. The protrusion can also be referred to as a post. The protrusion can also be referred to as a pillar. That is, as a pitch of a terminal 225 of the semiconductor device 220 becomes finer, a problem of the conductive adhesive disposed on the plurality of terminals 225 being short-circuited can occur. Therefore, in order to reduce a volume of a conductive adhesive disposed on each of the plurality of terminals 225, the first electrode pattern 120a-1 can include a protrusion. In addition, when using TC (Thermal Compression) bonding that applies heat and pressure to a conductive adhesive disposed between the first electrode pattern 120a-1 and the terminal 225 of the semiconductor device 220 to bond them, the protrusion may also function to improve an alignment between the first electrode pattern 120a-1 and the terminal 225 of the semiconductor device 220 and prevent diffusion of the conductive adhesive.

The electrode layer 120 of the substrate 100 may be formed of at least one metal material selected from gold (Au), silver (Ag), platinum (Pt), titanium (Ti), tin (Sn), copper (Cu), and zinc (Zn). In addition, the electrode layer 120 of the substrate 100 may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the electrode layer 120 of the substrate 100 may be formed of copper (Cu) having high electrical conductivity and relatively low price.

The electrode layer 120 of the substrate 100 may have a thickness in a range of 7 μm to 20 μm. For example, the electrode layer 120 of the substrate 100 may have a thickness in a range of 9 μm to 17 μm. The electrode layer 120 of the substrate 100 may have a thickness in a range of 10 μm to 13 μm. If the thickness of the electrode layer 120 of the substrate 100 is less than 7 μm, a resistance of the electrode layer 120 may increase and an allowable current of a transmittable signal may decrease. In addition, if the thickness of the electrode layer 120 of the substrate 100 exceeds 20 μm, it may be difficult to miniaturize the electrode layer 120.

The electrode layer 120 of the substrate 100 may include a through pad connected to the through electrode 130 of the substrate 100, and at least one electrode pattern connected to an external substrate or semiconductor device. In addition, the electrode layer 120 of the substrate 100 may include a trace of a signal transmission line connected to the through pad or the electrode pattern.

The through pad or electrode pattern of the electrode layer 120 of the substrate 100 may have a width in a range of 15 μm to 90 μm. The through pad or electrode pattern of the electrode layer 120 of the substrate 100 may have a width in a range of 20 μm to 85 μm. The through pad or electrode pattern of the electrode layer 120 of the substrate 100 may have a width in a range of 25 μm to 80 μm.

At this time, the through pad or electrode pattern of the electrode layer 120 of the substrate 100 may have different widths within the above-described range depending on the function. In addition, the electrodes of the electrode layer 120 of the substrate 100 may have different widths corresponding to a size of the terminal of the connected semiconductor device or a size of a pad of the external substrate.

For example, the electrode layer 120 of the substrate 100 may include a plurality of electrode patterns. For example, the electrode layer 120 of the substrate 100 may include a first electrode layer 120a disposed on the upper surface of the insulating layer 110. In addition, the first electrode layer 120a may include a plurality of electrode patterns. For example, the first electrode layer 120a may include a first electrode pattern 120a-1 that vertically overlaps the semiconductor device 220. The first electrode pattern 120a-1 may mean a pattern that is directly connected to the terminal 225 of the semiconductor device 220. In addition, the first electrode layer 120a may include a second electrode pattern 120a-2 that does not vertically overlap the semiconductor device 220.

The first electrode pattern 120a-1 is directly connected to the terminal 225 of the semiconductor device 220. The terminal 225 of the semiconductor device 220 is provided in multiple pieces, and accordingly, the first electrode pattern 120a-1 may also be provided in multiple pieces. At this time, a shape, a size, and a pitch of at least one electrode pattern among the multiple first electrode patterns 120a-1 may be different from a shape, a size, and a pitch of at least one other electrode pattern.

If the first electrode pattern 120a-1 includes a protrusion, a width of the protrusion may range from 4 μm to 70 μm. If the width of the protrusion is smaller than 40 μm, the width of the protrusion may be too small, causing a problem of collapse during TC bonding. In addition, if the width of the protrusion is larger than 70 μm, it may be difficult to correspond to a fine pitch of the terminal 225 of the semiconductor device 220.

The substrate 100 may include a through electrode 130. The through electrode 130 of the substrate 100 can pass through the insulating layer 110 of the substrate 100. The through electrode 130 of the substrate 100 can connect between electrode layers disposed in different insulating layers of the substrate 100. The through electrode 130 may mean an electrode connecting the electrode layer 120 and the first electrode pattern 120a-1 or the electrode layer 120 and the second electrode pattern 120-2. A width of the through electrode 130 may be smaller than a width of the first electrode pattern 120a-1 and/or the second electrode pattern 120-2. In addition, a vertical thickness of the through electrode 130 may be larger than a vertical thickness of the first electrode pattern 120a-1 and/or the second electrode pattern 120-2. When the electrode layer is embedded in the insulating layer, the through electrode 130 can penetrate between the electrode layers disposed in the insulating layer. In addition, when the electrode layers protrude from the upper and lower surfaces of the insulating layer, the through electrode 130 can entirely penetrate the insulating layer.

The through electrode 130 of the substrate 100 can be formed by filling an inside of the through hole passing through the insulating layer 110 of the substrate 100 with a conductive material.

The through hole can be formed by any one of mechanical, laser, and chemical processing methods. When the through hole is formed by mechanical processing, methods such as milling, drilling, and routing can be used. In addition, when the through hole is formed by laser processing, a UV or CO₂ laser method can be used. In addition, when the through hole is formed by chemical processing, a chemical agent including amino silane, ketones, etc. can be used.

When the through hole is formed, the inside of the through hole can be filled with a conductive material to form a through electrode 130 of the substrate 100. A metal material forming the through electrodes can be any one material selected from copper (Cu), silver (Ag), tin (Sn), gold (Au), nickel (Ni), and palladium (Pd). In addition, the conductive material filling can use any one of electroless plating, electrolytic plating, screen printing, sputtering, evaporation, ink-jetting, and dispensing, or a combination thereof.

The semiconductor package of the first embodiment can include a first protective layer 140 disposed on the substrate 100. In addition, the semiconductor package can include a second protective layer 150 disposed under the substrate 100. At this time, the upper surface of the package substrate may mean the upper surface of the first protective layer 140, and the lower surface of the package substrate may mean the lower surface of the second protective layer 150. However, when the package substrate does not include the first and second protective layers 140 and 150, the upper surface and lower surface of the package substrate may mean the upper surface and lower surface of the substrate 100.

The first protective layer 140 and the second protective layer 150 may have a function of protecting the substrate 100. For example, the first protective layer 140 and the second protective layer 150 may have a function of protecting a surface of the insulating layer 110 or a surface of the electrode layer 120 of the substrate 100. Accordingly, the first protective layer 140 and the second protective layer 150 may also be functionally expressed as ‘protective layers’.

For example, the first protective layer 140 and the second protective layer 150 may be resist layers. Preferably, the first protective layer 140 and the second protective layer 150 may be solder resist layers including an organic polymer material. For example, the first protective layer 140 and the second protective layer 150 may include an epoxy acrylate series resin. In detail, the first protective layer 140 and the second protective layer 150 may include a resin, a curing agent, a photoinitiator, a pigment, a solvent, a filler, an additive, an acrylic series monomer, and the like. However, the embodiment is not limited thereto, and the first protective layer 140 and the second protective layer 150 may of course be any one of a photo solder resist layer, a cover-lay, and a polymer material.

A thickness of each of the first protective layer 140 and the second protective layer 150 may be 1 μm to 20 μm. The thickness of each of the first protective layer 140 and the second protective layer 150 may be 1 μm to 15 μm. For example, the thickness of each of the first protective layer 140 and the second protective layer 150 may be 5 μm to 20 μm. If the thickness of each of the first protective layer 140 and the second protective layer 150 exceeds 20 μm, the thickness of the semiconductor package may increase, or stress may be applied to the substrate 100. If the thickness of each of the first protective layer 140 and the second protective layer 150 is less than 1 μm, the electrode layer 120 included in the substrate 100 is not stably protected, and thus, electrical reliability or physical reliability may be deteriorated.

The first protective layer 140 may be divided into a plurality of regions in a horizontal direction. For example, it may include a circumferential region 140a or an outer region or an edge region adjacent to a circumference 140c of an upper surface of the first protective layer 140. In addition, the first protective layer 140 may include an inner region 140b excluding the circumferential region 140a.

In addition, the first protective layer 140 may include a plurality of open regions. For example, the first protective layer 140 includes an upper surface and a lower surface opposite to the upper surface.

In addition, the first protective layer 140 may include a plurality of open regions penetrating the upper surface and the lower surface. The open region may also be referred to as ‘opening’.

For example, the first protective layer 140 may include a first opening 141 provided in a circumferential region 140a adjacent to a circumference 140c of an upper surface of the first protective layer 140. In addition, the first protective layer 140 may include a second opening 142 provided in the inner region 140b

At this time, a planar shape of the first opening 141 of the first protective layer 140 may be different from a planar shape of the second opening 142, but is not limited thereto.

A diameter of the first opening 141 of the first protective layer 140 may be different from a diameter of the second opening 142. Preferably, the first opening 141 of the first protective layer 140 may have a diameter larger than the diameter of the second opening 142. That is, an open area of the first protective layer 140 by one first opening 141 may be larger than an open area of the first protective layer 140 by one second opening 142.

The first opening 141 and the second opening 142 may have different functions.

The first opening 141 may function as a vent hole. Accordingly, the first opening 141 may be provided adjacent to an outer side surface of the first protective layer 140. In addition, the first opening 141 may have a larger diameter than the second opening 142 in order to improve gas discharge performance.

The second opening 142 may vertically overlap the first electrode pattern 120a-1 of the first electrode layer 120a. Accordingly, the second opening 142 may have a diameter corresponding to a width of the first electrode pattern 120a-1 of the first electrode layer 120a. The second opening 142 may have a function of opening the first electrode pattern 120a-1 electrically connected to the terminal 225 of the semiconductor device 220 among the first electrode layer 120a from the first protective layer 140. Accordingly, the second opening 142 may have a diameter smaller than that of the first opening 141. Meanwhile, the diameter may mean a width in a first horizontal direction or a width in a second horizontal direction, but is not limited thereto.

The diameter of the first opening 141 may be determined according to a total area of the substrate 100 and an amount of adhesive member 240 applied accordingly. For example, the diameter of the first opening 141 may increase in proportion to an area of the substrate 100 or an amount of adhesive member 240 applied.

Meanwhile, a diameter of the second opening 142 may be determined by a width of the first electrode pattern 120a-1 of the first electrode layer 120a. At this time, a width of the first electrode pattern 120a-1 is also becoming smaller due to the miniaturization of the terminal 225 of the semiconductor device 220. Therefore, the diameter of the second opening 142 may be smaller than the diameter of the first opening 141.

In one embodiment, the first opening 141 may not vertically overlap the first electrode layer 120a. For example, the first opening 141 may not vertically overlap with the first electrode pattern 120a-1 and the second electrode pattern 120a-2 of the first electrode layer 120a. Therefore, the first opening 141 may expose the upper surface of the insulating layer 110 of the substrate 100, not the upper surface of the first electrode layer 120a.

In another embodiment, the first opening 141 may vertically overlap with at least one electrode pattern of the first electrode layer 120a. For example, the first electrode layer 120a may include an electrode pattern corresponding to a ground electrode having a ground function, or an electrode pattern corresponding to a heat dissipation electrode having a heat dissipation function. In addition, the first opening 141 may vertically overlap with a ground electrode pattern or a heat dissipation electrode pattern of the first electrode layer 120a. Accordingly, the embodiment allows the heat transmitted through the ground electrode pattern or the heat dissipation electrode pattern to be dissipated to the outside while discharging gas through the first opening 141.

Unlike this, the second opening 142 may be provided to expose the first electrode pattern 120a-1 of the first electrode layer 120a that is coupled with the terminal 225 of the semiconductor device 220. For example, the second opening 142 may be provided in a bonding region between the terminal 225 of the semiconductor device 220 and the first electrode pattern 120a-1 of the first electrode layer 120a. At this time, the bonding between the terminal 225 of the semiconductor device 220 and the first electrode pattern 120a-1 of the first electrode layer 120a may mean wire bonding, solder bonding, direct bonding between metals, etc. Wire bonding may mean electrically connecting the terminal 225 of the semiconductor device 220 and the first electrode pattern 120a-1 using a conductor such as gold (Au). In addition, the solder bonding may mean electrically connecting the terminal 225 of the semiconductor device 220 and the first electrode pattern 120a-1 using a material including at least one of Sn, Ag, and Cu. In addition, the direct bonding between metals may mean applying heat and pressure to the first electrode pattern 120a-1 and the terminal 225 of the semiconductor device 220 to recrystallize without solder, wire, conductive adhesive, etc., thereby directly connecting the first electrode pattern 120a-1 and the terminal 225 of the semiconductor device.

Meanwhile, the first opening 141 may be connected to an outer side surface of the first protective layer 140. That is, the first opening 141 may mean a through hole that is concave inwardly from the outer side surface of the first protective layer 140 and passes through the upper and lower surfaces of the first protective layer 140.

In contrast, the second opening 142 may be spaced apart from the first opening 141 and also spaced apart from the outer side surface of the first protective layer 140.

Meanwhile, the second protective layer 150 may also include an opening. The opening of the second protective layer 150 may overlap vertically with an electrode pattern disposed on a lower surface of the insulating layer 110 of the substrate 100.

The semiconductor package of the embodiment includes a first connection part 210. That is, the first connection part 210 is disposed on the substrate 100. For example, a first connection part 210 is disposed on a first electrode pattern 120a-1 of a first electrode layer 120a of the substrate 100. At this time, if the first electrode pattern 120a-1 and the terminal 225 of the semiconductor device 220 are bonded by direct bonding between metals, the first connection part 210 may be omitted. Alternatively, if the first electrode pattern 120a-1 and the terminal 225 of the semiconductor device 220 are bonded by direct bonding between metals, the first connection part 210 may mean a metal layer recrystallized by the direct bonding.

The first connection part 210 may have a hexahedral shape. A cross-section of the first connection part 210 may include a square shape. The cross-section of the first connection part 210 may include a rectangle or a square. For example, the first connection part 210 may include a spherical shape. For example, the cross-section of the first connection part 210 may include a circular shape or a semicircular shape. For example, the cross-section of the first connection part 210 may include a partially or entirely rounded shape. A cross-sectional shape of the first connection part 210 may be flat on one side and curved on another side. The first connection part 210 may be a solder ball, but is not limited thereto.

The semiconductor package of the embodiment includes a component disposed on the first connection part 210. The component disposed on the first connection part 210 may be a semiconductor device, or alternatively, may be an interposer. Hereinafter, the component disposed on the first connection part 210 is described as a semiconductor device 220.

The semiconductor device 220 may be a logic chip, but is not limited thereto. For example, the semiconductor device 220 may be an application processor (AP) chip among a central processor (e.g., CPU), a graphic processor (e.g., GPU), a digital signal processor, an encryption processor, a microprocessor, and a microcontroller. The semiconductor device 220 includes a terminal 225 provided on the lower surface of the semiconductor device 220. In addition, the terminal 225 of the semiconductor device 220 may be electrically connected to the first electrode pattern 120a-1 of the electrode layer 120 of the substrate 100 through the first connection part 210.

In addition, the semiconductor package may include a molding member 230. The molding member 230 may mold a part of the configuration coupled to the substrate 100. The molding member 230 may mean an underfill molding a side of the semiconductor device 220. In addition, the molding member 230 may mean a molding layer molding a side of the semiconductor device 220. In addition, the molding member 230 may include both the underfill and the molding layer.

The molding member 230 may mold the first connection part 210. In addition, the molding member 230 may mold a terminal 225 of the semiconductor device 220. In addition, the molding member 230 may mold at least a part of a side of the semiconductor device 220. The molding member 230 may open an upper surface of the semiconductor device 220.

The molding member 230 may be EMC (Epoxy Mold Compound), but the embodiment is not limited thereto. The molding member 230 may have a low dielectric constant. For example, the dielectric constant (Dk) of the molding member 230 may be 0.2 to 10. For example, the dielectric constant (Dk) of the molding member 230 may be 0.5 to 8. For example, the dielectric constant (Dk) of the molding member 230 may be 0.8 to 5. Accordingly, in the embodiment, the molding member 230 has a low dielectric constant so that heat generated from the semiconductor device 220 can be efficiently dissipated to the outside.

The semiconductor package includes a second connection part 260.

The second connection part 260 may be disposed on the lower surface of the substrate 100. For example, the second connection part 260 may be disposed on the lower surface of the electrode pattern of the electrode layer 120 disposed on the lower surface of the substrate 100. For example, the second connection part 260 may be disposed in an opening of the second protective layer 150. The second connection part 260 may be a solder for connecting the semiconductor package of the embodiment to a separate external substrate (e.g., a main board of an electronic device), but is not limited thereto.

The semiconductor package includes an adhesive member 240.

The adhesive member 240 may be disposed on an upper surface of the first protective layer 140. Preferably, the adhesive member 240 may include a material having adhesive properties. The adhesive member 240 may be epoxy, but is not limited thereto. For example, the adhesive member 240 may be any one of a thermosetting adhesive, an ultraviolet-curable adhesive, and an adhesive film.

The adhesive member 240 may be disposed on the upper surface of the first protective layer 140 along the circumferential direction of the upper surface of the first protective layer 140. The circumferential direction may mean an edge direction provided along an edge of the upper surface of the first protective layer 140.

For example, the adhesive member 240 may be disposed in the circumferential region 140a of the upper surface of the first protective layer 140 along the circumferential direction of the upper surface of the first protective layer 140. That is, the circumferential region 140a is provided along the circumferential direction of the upper surface of the first protective layer 140 while being adjacent to the circumference 140c of the upper surface of the first protective layer 140. In addition, the adhesive member 240 may be disposed in the circumferential region 140a of the first protective layer 140.

At this time, the adhesive member 240 may be disposed in an open-loop shape along the circumferential direction of the upper surface of the first protective layer 140. For example, the adhesive member 240 may not be disposed entirely but partially in the circumferential region 140a of the first protective layer 140. For example, the circumferential region 140a of the first protective layer 140 may include an adhesive member disposition region in which the adhesive member 240 is disposed and an adhesive member non-disposition region in which the adhesive member 240 is not disposed. The adhesive member non-disposition region may mean a separation region between one end and another end of the adhesive member 240 having an open-loop shape.

Through this, the embodiment allows the adhesive member 240 to have an open loop shape, and thus, the adhesive member 240 is not disposed in at least a part of the circumferential region 140a of the first protective layer 140. In addition, a region of the circumferential region 140a where the adhesive member 240 is not disposed can function as a vent hole. For example, when the adhesive member 240 has a closed loop shape, a gas existing in a cavity space defined as an inner space of the cover member 300 may not be discharged to an outside of the cavity space. That is, the embodiment can perform a thermal process for combining the adhesive member 240 and the cover member 300. In addition, a gas may be generated in the inner space during the thermal process. At this time, when the adhesive member 240 has the closed loop shape, a gas generated in the cavity space may not be discharged to the outside. Therefore, in the embodiment, the adhesive member 240 is provided to have an open loop shape, and through this, the gas existing in the cavity space can be discharged to the outside of the cavity space through the separation region between one end and the other end of the adhesive member 240.

However, the separation region between one end and the other end of the adhesive member 240 alone may not be sufficient to discharge the gas existing in the cavity space to the outside. That is, due to the high specification of the semiconductor package, an area of the semiconductor package is increasing. Accordingly, an amount of the adhesive member 240 applied is increasing. Accordingly, if the gas is discharged only through the separation region between one end and the other end of the adhesive member 240, the gas inside the cavity space cannot be sufficiently discharged to the outside, and thus a physical reliability problem may occur. At this time, an area of the separation region where the adhesive member 240 is not disposed may be increased to secure a space through which the gas can be discharged. However, as an area of the semiconductor package increases, a size of the cover member 300 also increases. In addition, when the area of the separation region increases, the adhesion between the cover member 300 and the substrate 100 may not be sufficiently secured, which may cause a physical reliability problem in which the cover member 300 is separated from the substrate 100. In other words, when the area of the separation region decreases, a problem occurs in which the gas is not sufficiently discharged, and when the area of the separation region increases, a problem occurs in which the adhesion between the cover member 300 and the substrate 100 is not secured.

Therefore, the embodiment uses the first opening 141 provided in the first protective layer 140 to allow the gas present in the cavity space to be discharged outside the cavity space.

To this end, the first opening 141 of the first protective layer 140 may vertically overlap with the separation region of the adhesive member 240. In other words, the first opening 141 of the first protective layer 140 can be connected to the separation region of the adhesive member 240. Therefore, the embodiment can discharge gas existing in the cavity space not only through the separation region but also through the first opening 141 of the first protective layer 140 connected to the separation region.

In other words, the circumferential region 140a of the first protective layer 140 includes a disposition region where the adhesive member 240 is disposed and a non-disposition region where the adhesive member 240 is not disposed. In addition, the first opening 141 of the first protective layer 140 vertically overlaps the non-disposition region of the circumferential region 140a. Accordingly, a separation distance in a vertical direction between the lower surface of the cover member 300 and the substrate 100 can increase by a depth of the first opening 141. Through this, the embodiment can sufficiently discharge the gas generated in the cavity space to the outside. Accordingly, the embodiment can further improve the physical reliability and electrical reliability of the semiconductor package.

The semiconductor package includes a cover member 300.

The cover member 300 is disposed on the adhesive member 240. The cover member 300 can include an inner accommodation space defined as a cavity space.

The cover member 300 can have a shape in which a lower side is open while including the accommodation space on the inside.

The cover member 300 includes a side plate portion 310 disposed on the substrate 100 and covering a side of the semiconductor device 220. In addition, the side plate portion 310 may include a first portion in contact with the adhesive member 240 and a second portion extending from the first portion in a direction away from the substrate. For example, the side plate portion 310 may have a step shape, but is not limited thereto.

The cover member 300 includes an upper plate portion 320 extending from an upper end of the side plate portion 310 and covering an upper portion of the semiconductor device 220. In addition, the cover member 300 may form a cavity space that accommodates the semiconductor device 220 on the inside through the side plate portion 310 and the upper plate portion 320.

A lower surface of the cover member 300 may be in contact with the adhesive member 240. Specifically, a lower surface of the side plate portion 310 of the cover member 300 may be in contact with the adhesive member 240.

At this time, the lower surface of the side plate portion 310 of the cover member 300 may include a first lower surface vertically overlapping the adhesive member 240 and in contact with the adhesive member 240. In addition, the lower surface of the side plate portion 310 of the cover member 300 may include a second lower surface that does not vertically overlap with the adhesive member 240 and does not contact the adhesive member 240. For example, the second lower surface of the side plate portion 310 of the cover member 300 may be a portion vertically overlapping the separation region of the adhesive member 240. At this time, the second lower surface of the side plate portion 310 of the cover member 300 may vertically overlap with the first opening 141 of the first protective layer 140. Accordingly, at least a portion of the second lower surface of the side plate portion 310 of the cover member 300 may be positioned to directly face the upper surface of the substrate 100 through the separation region and the first opening 141.

The cover member 300 may vertically overlap the electrode layer 120. The upper plate portion 320 of the cover member 300 may vertically overlap the semiconductor device 220 and/or the electrode layer 120. In addition, the side plate portion 310 of the cover member 300 may vertically overlap the electrode layer 120. The side plate portion 310 may include a first region vertically overlapping the first opening 141 and a second region vertically overlapping the first adhesive member 240. In addition, when the first region does not vertically overlap the first protective layer 140, the first region may not vertically overlap the electrode layer 120 in order to prevent the electrode layer 120 from being oxidized or deteriorated by gas flowing through the first opening 141. However, since the electrode layer 120 is protected from the flowing gas by the first protective layer 140 and/or the first adhesive member 240 in the second region, a wiring design of the electrode layer 120 may be freely performed, and thus the second region may vertically overlap the electrode layer 120.

The cover member 300 covers a periphery of the cavity space, and thus can have a function of protecting the semiconductor device 220 accommodated in the cavity space. In addition, the cover member 300 can have a dissipation function of dissipating heat generated from the semiconductor device 220 to the outside. To this end, the cover member 300 may include a metal material having excellent heat transfer characteristics, but is not limited thereto.

Meanwhile, the semiconductor package of the embodiment includes a second adhesive member 410. The second adhesive member 410 may be disposed on the upper surface of the semiconductor device 220. In addition, the second adhesive member 410 may be disposed on the lower surface of the upper plate portion 320 of the cover member 300. Specifically, the second adhesive member 410 may be disposed between the semiconductor device 220 and the cover member 300. The second adhesive member 410 allows the cover member 300 to be coupled to the semiconductor device 220. In addition, the second adhesive member 410 can transfer heat generated from the semiconductor device 220 to the cover member 300. To this end, the second adhesive member 410 may include a material having excellent heat transfer characteristics. For example, the second adhesive member 410 may be a TIM (Thermal Interface Material) capable of heat transfer. Preferably, the second adhesive member 410 may be a TIM paste. The TIM paste may be composed of a mixture of alumina, wax, solvent, etc., but is not limited thereto.

In addition, the semiconductor package includes a third adhesive member 420. The third adhesive member 420 is disposed on the cover member 300. Preferably, the third adhesive member 420 is disposed on the upper surface of the upper plate portion 320 of the cover member 300. The third adhesive member 420 may be disposed between a heat dissipation plate 430 and the cover member 300. The third adhesive member 420 may allow the heat dissipation plate 430 to be coupled onto the cover member 300. The third adhesive member 420 may transfer heat transferred from the cover member 300 to the heat dissipation plate 430. To this end, the third adhesive member 420 may include a material having excellent heat transfer properties. For example, the third adhesive member 420 may be a TIM paste, but is not limited thereto.

The semiconductor package includes a heat dissipation plate 430 coupled onto the third adhesive member 420. The heat dissipation plate 430 may be a heat sink. The heat dissipation plate 430 can release heat transferred from the cover member 300 to the outside. The heat dissipation plate 430 may have a structure including a plurality of heat dissipating fins spaced apart from each other, but is not limited thereto.

FIG. 2 is a cross-sectional view showing a semiconductor package according to a second embodiment.

Referring to FIG. 2, the semiconductor package of the second embodiment may be different from the semiconductor package of the first embodiment in a structure of the substrate 100. Therefore, only the structure of the substrate 100 will be described below.

The semiconductor package of the first embodiment has a structure in which one semiconductor device 220 is mounted on the substrate 100. Unlike this, the semiconductor package of the second embodiment may have a plurality of semiconductor devices mounted spaced apart from each other in the horizontal direction on the substrate 100.

In addition, the substrate 100 of the first embodiment was a package substrate. That is, the substrate 100 of the first embodiment is a package substrate disposed between the semiconductor device and the main board.

Unlike this, the substrate 100 of the second embodiment is an interposer. That is, the substrate 100 of the second embodiment may mean an interposer disposed between the semiconductor device and the package substrate 600.

In addition, the first electrode pattern 120a-1 of the first electrode layer 120a may be divided into a first electrode pattern of a first group and a second electrode pattern of a second group.

In addition, the semiconductor package of the second embodiment may include a first semiconductor device 220a disposed on the first electrode pattern of the first group. A terminal 225a of the first semiconductor device 220a may be electrically connected to the first electrode pattern of the first group through the first connection part 210.

In addition, the semiconductor package of the second embodiment may include a second semiconductor device 220b disposed on the second electrode pattern of the second group. A terminal 225b of the second semiconductor device 220b may be electrically connected to the first electrode pattern of the second group through the first connection part 210.

The first semiconductor device 220a and the second semiconductor device 220b may be a same type of logic chip, or may be different types of logic chips.

Meanwhile, the molding member 230 of the semiconductor package of the second embodiment may simultaneously mold the first semiconductor device 220a and the second semiconductor device 220b.

In addition, the second adhesive member 410 of the semiconductor package of the second embodiment may be disposed on the first semiconductor device 220a and the second semiconductor device 220b. At this time, the second adhesive member 410 may also be disposed in a separation region between the first semiconductor device 220a and the second semiconductor device 220b, but is not limited thereto.

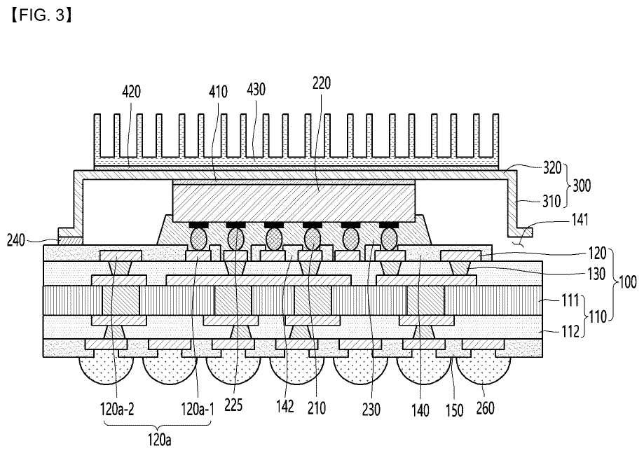

FIG. 3 is a cross-sectional view showing a semiconductor package according to a third embodiment.

Referring to FIG. 3, the semiconductor package of the third embodiment may be different from the semiconductor package of the first embodiment in a structure of the substrate 100. Therefore, only the structure of the substrate 100 will be described below.

The semiconductor package of the first embodiment of FIG. 1 may be a core-less substrate. In addition, the semiconductor package of the third embodiment of FIG. 3 may be a core substrate.

Referring to FIG. 3, the substrate 100 includes an insulating layer 110. In addition, the insulating layer 110 may have a multi-layer structure. The insulating layer 110 may include a core layer 111. The core layer 111 may include a prepreg. The prepreg may be formed by impregnating a fiber layer in the form of a fabric sheet, such as a glass fabric woven with glass fiber yarn, with an epoxy resin or the like, and then performing heat compression. The core layer 111 may include a resin and reinforcing fibers disposed in the resin. The resin may be an epoxy resin, but is not limited thereto.

The insulating layer 110 of the substrate 100 may further include an additional insulating layer 112 disposed on the core layer 111. The additional insulating layer 112 may be ABF that does not include a reinforcing material included in the substrate 100 of the first embodiment.

At this time, the electrodes of the electrode layer 120 of the substrate 100 of the second embodiment may have a structure protruding on the upper surface of the insulating layer 110 of the substrate 100.

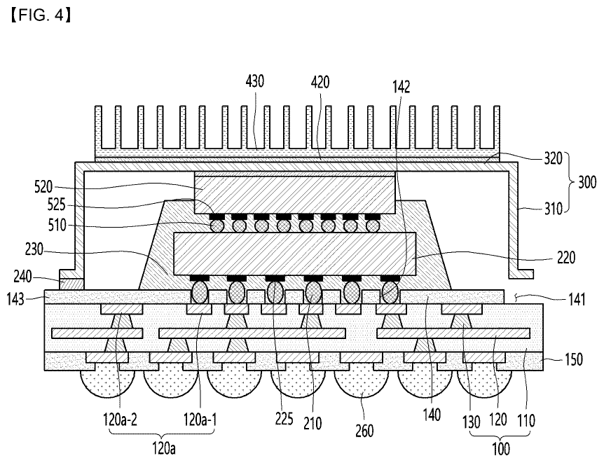

FIG. 4 is a cross-sectional view showing a semiconductor package according to a fourth embodiment.

Referring to FIG. 4, the semiconductor package of the fourth embodiment may be different from the semiconductor package of the first embodiment in a component of the semiconductor device disposed on the substrate 100. Therefore, only the component of the semiconductor device disposed on the substrate 100 will be described below.

The semiconductor package of the fourth embodiment may include a first component 220 disposed on a first connection part 210 of the substrate 100. The first component 220 may be a semiconductor device, or alternatively, an interposer. In addition, when the first component 220 is an interposer, it may be an active interposer, or alternatively, a passive interposer.

In addition, the semiconductor package of the fourth embodiment may include a fifth connection part 510 disposed on the first component 220. The fifth connection part 510 may be electrically connected to the first component 220. For example, when the first component 220 is a semiconductor device, the fifth connection part 510 may be disposed on a terminal of the semiconductor device. For example, if the first component 220 is an interposer, the fifth connection part 510 may be disposed on the electrode of the interposer.

In addition, the semiconductor package of the fourth embodiment may include a second component 520 disposed on the fifth connection part 510. The second component 520 may be a semiconductor device. For example, the second component 520 may be a CPU or a GPU, but is not limited thereto. The second component 520 includes a terminal 525. In addition, the terminal 525 of the second component 520 may be electrically connected to the first component 220 through the fifth connection part 510. Through this, the second component 520 may be electrically connected to the substrate 100.

For example, the semiconductor package of the fourth embodiment may have a plurality of semiconductor devices 220 and 520 disposed in a stacked structure on the substrate 100. In addition, the semiconductor package of the third embodiment may have the substrate 100 and the semiconductor device 520 electrically connected through an active or passive interposer 220.

In addition, the molding member 230 of the fourth embodiment may mold the first component 220 and the second component 520.

In addition, the cover member 300 of the fourth embodiment may cover the side and upper regions of the first component 220 and the second component 520. For example, the first component 220 and the second component 520 may be disposed in the cavity space defined as an accommodation space of the cover member 300.

In addition, the second adhesive member 410 of the fourth embodiment may be disposed on the upper surface of the second component 520.

Hereinafter, a structure of the open region of the first protective layer 140, an arrangement structure of the first adhesive member 240, and an arrangement structure of the cover member 300 will be described in more detail.

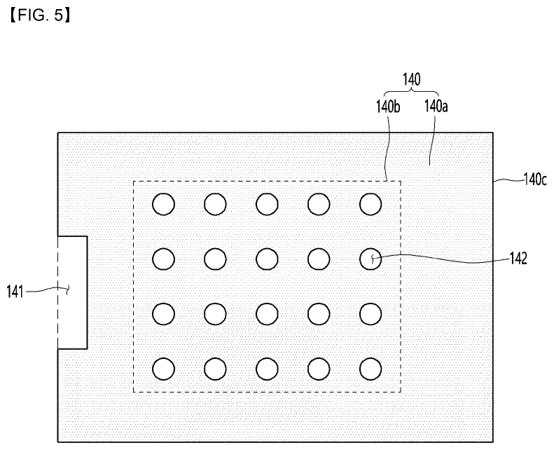

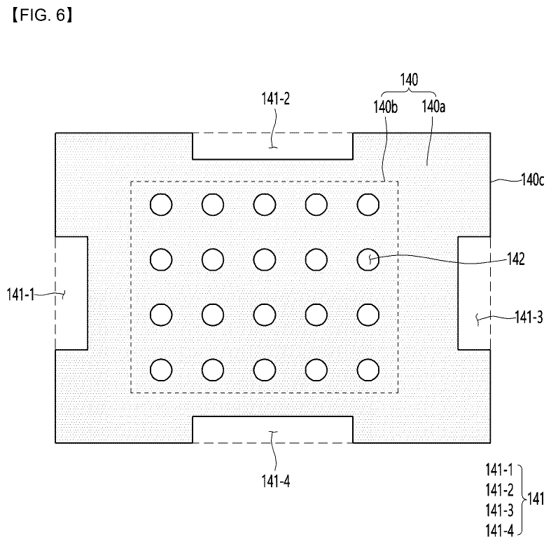

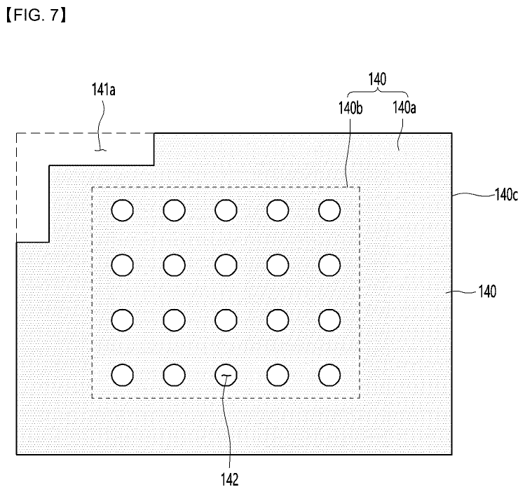

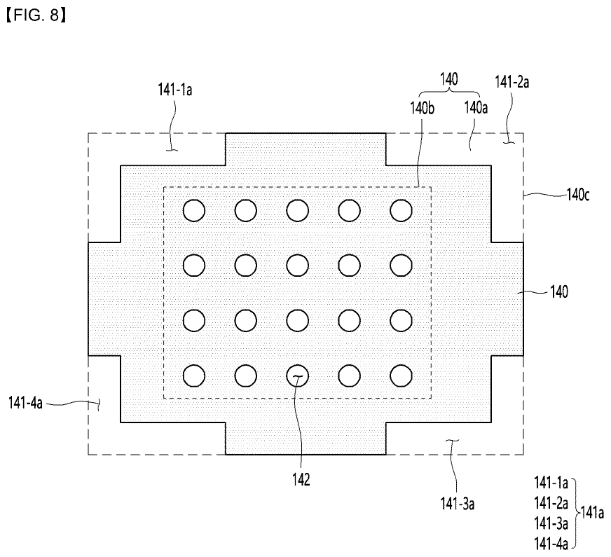

FIG. 5 is a plan view showing a first protective layer of a first embodiment, FIG. 6 is a plan view showing a first protective layer of a second embodiment, FIG. 7 is a plan view showing a first protective layer of a third embodiment, FIG. 8 is a plan view showing a first protective layer of a fourth embodiment, FIG. 9 is a drawing showing a state where a first adhesive member is disposed on a first protective layer of a first embodiment, and FIG. 10 is a drawing showing a state where a first adhesive member is disposed on a first protective layer of a second embodiment.

Referring to FIG. 5, the first protective layer 140 is disposed on the substrate 100. The first protective layer 140 may include an open region.

At this time, the first protective layer 140 may be divided into a plurality of regions. For example, the first protective layer 140 may include a circumferential region 140a adjacent to a circumference 140c of the upper surface of the first protective layer 140. In addition, the first protective layer 140 may include an inner region 140b excluding the circumference 140c.

At this time, the circumference 140c may also be referred to as an edge of the upper surface of the first protective layer 140. In addition, the circumference 140c may also be referred to as a corner of the upper surface of the first protective layer 140 that is connected to an outer side surface of the first protective layer 140.

The open region of the first protective layer 140 includes a first opening 141 and a second opening 142.

At this time, the first opening 141 in the first embodiment may be provided of one.

The first opening 141 may be provided in the circumferential region 140a of the first protective layer 140. The first opening 141 may be a through hole penetrating the upper and lower surfaces of the circumferential region 140a of the first protective layer 140. At this time, the first opening 141 may be connected to the outer side surface of the first protective layer 140. Accordingly, the first opening 141 may be a recess concave inwardly in the outer side surface of the first protective layer 140, and may be said to be a through hole penetrating the upper and lower surfaces of the first protective layer 140.

The second openings 142 may be configured in plurality. A number of the second openings 142 may correspond to a number of terminals 225 of the semiconductor device 220 disposed on the substrate 100 or a number of the first electrode patterns 120a-1, but is not limited thereto. For example, the number of the second openings 142 may be smaller than the number of the first electrode patterns 120a-1. In this case, at least one of the plurality of second openings may open the plurality of first electrode patterns 120a-1 simultaneously.

In the first embodiment, the first opening 141 may be provided in a region spaced apart from a corner region among the circumferential region 140a regions of the first protective layer 140.

Referring to FIG. 6, the first opening 141 in the second embodiment may be provided of a plurality of pieces.

For example, the first protective layer 140 of the second embodiment may include a plurality of first openings 141 that are provided in the circumferential region 140a and spaced apart from each other.

For example, the plurality of first openings 141 may include first-first to first-fourth openings 141-1, 141-2, 141-3, and 141-4 that are spaced apart from each other in the circumferential region 140a. The first-first to first-fourth openings 141-1, 141-2, 141-3, and 141-4 may be spaced apart from each other along the circumferential direction of the upper surface of the first protective layer 140. In addition, each of the first-first to first-fourth openings 141-1, 141-2, 141-3, and 141-4 may be connected to the outer side surface of the first protective layer 140.

Referring to FIG. 7, the first protective layer 140 of the third embodiment may have one first opening 141a. At this time, the first opening 141 of the first protective layer 140 is disposed at a position spaced apart from a corner region of the upper surface of the first protective layer 140.

In contrast, the first opening 141a of the first protective layer 140 of the third embodiment may be disposed in the corner region. Accordingly, a circumference of the outer side surface of the first protective layer 140 constituting the first opening 141a may include a bent portion. For example, a planar shape of the first opening 141 of the third embodiment may have an “L” shape including a bent portion, but is not limited thereto.

Referring to FIG. 8, the first opening 141a of the fourth embodiment may be composed of a plurality of pieces.

For example, the first protective layer 140 of the fourth embodiment may include a plurality of first openings 141a that are provided in the circumferential region 140a and are spaced apart from each other.

For example, the plurality of first openings 141a may include first-first to first-fourth openings 141-1a, 141-2a, 141-3a, and 141-4a spaced apart from each other in the circumferential region 140a. The first-first to first-fourth openings 141-1a, 141-2a, 141-3a, and 141-4a may be spaced apart from each other along the circumferential direction of the upper surface of the first protective layer 140. In addition, each of the first-first to first-fourth openings 141-1a, 141-2a, 141-3a, and 141-4a may be connected to the outer side surface of the first protective layer 140. The first-first to first-fourth openings 141-1a, 141-2a, 141-3a, and 141-4a may be provided at different corner regions of the circumferential region 140a of the upper surface of the first protective layer 140.

Meanwhile, the first opening of the first protective layer 140 of the embodiment may also be provided as a combination of the structures of the first openings of at least two embodiments among the first to fourth embodiments.

Meanwhile, referring to FIG. 9, a first adhesive member 240 is disposed in the circumferential region 140a of the first protective layer 140. In addition, the first connection part 210 may be disposed in the second opening 142 of the first protective layer 140.

The first adhesive member 240 may be disposed in the circumferential region 140a of the first protective layer 140 along the circumferential direction of the upper surface of the first protective layer 140. At this time, the first adhesive member 240 may have an open loop shape. For example, the first adhesive member 240 may be partially disposed in the circumferential region 140a. For example, the circumferential region 140a may include a non-disposition region in which the first adhesive member 240 is not disposed along the circumferential direction. The non-disposition region may mean a separation region between one end 241e1 and the other end 241e2 of the first adhesive member 240 having the open loop shape. For example, the non-disposition region may mean a region vertically overlapping the second lower surface of the side plate portion 310 of the cover member 300. The second lower surface of the side plate portion 310 of the cover member 300 may mean a portion of the lower surface of the side plate portion 310 that does not vertically overlap with the adhesive member 240 and does not come into contact with the first adhesive member 240.

In addition, the first opening 141 of the first protective layer 140 may vertically overlap with the non-disposition region. At this time, the non-disposition region may vertically partially overlap with the first opening 141 of the first protective layer 140.

Specifically, a part of the non-disposition regions may be provided with the first opening 141, and a part of a remaining region may not be provided with the first opening 141.

Specifically, the first opening 141 of the embodiment may have a first width W1. At this time, the first width W1 may mean a width in the circumferential direction of the upper surface of the first protective layer 140. For example, the first width may mean a length in a horizontal direction of the first opening 141.

In addition, the non-disposition region or the separation region of the embodiment may have a second width W2 greater than the first width W1. The second width W2 may mean a width in the circumferential direction of the upper surface of the first protective layer 140. For example, the second width W2 may mean a separation distance of the separation region. For example, the second width W2 may mean a separation distance between one end 240e1 and the other end 240e2 of the first adhesive member 240.

In the embodiment, the first width W1 is made larger than the second width W2. Through this, the embodiment can guide a discharge path of the gas existing in the cavity space toward the first opening 141. Through this, the embodiment can further improve the gas discharge characteristics.

In addition, in the embodiment, the first width W1 is made larger than the second width W2, and through this, the first adhesive member 240 disposed on the first protective layer 140 can be prevented from overflowing into the first opening 141. Accordingly, the embodiment can further improve the gas discharge characteristics without affecting the gas discharge characteristics.

Meanwhile, referring to FIG. 10, the first opening 141 can be provided in multiple pieces.

For example, the first opening 141 may include first-first to first-fourth openings 141-1, 141-2, 141-3, and 141-4 that are spaced apart from each other in the circumferential region 140a and provided along the circumferential direction of the upper surface of the first protective layer 140.

Accordingly, the first adhesive member 240 may include a plurality of adhesive patterns disposed along the circumferential direction between the first-first to first-fourth openings 141-1, 141-2, 141-3, and 141-4.

For example, the first adhesive member 240 may include a first adhesive pattern 241-1 disposed along the circumferential direction between the first-first opening 141-1 and the first-second opening 141-2.

For example, the first adhesive member 240 may include a second adhesive pattern 241-2 disposed along the circumferential direction between the first-second opening 141-2 and the first-third opening 141-3.

For example, the first adhesive member 240 may include a third adhesive pattern 241-3 disposed along the circumferential direction between the first-third opening 141-3 and the first-fourth opening 141-4.

For example, the first adhesive member 240 may include a fourth adhesive pattern 241-4 disposed along the circumferential direction between the first-first opening 141-1 and the first-fourth opening 141-4.

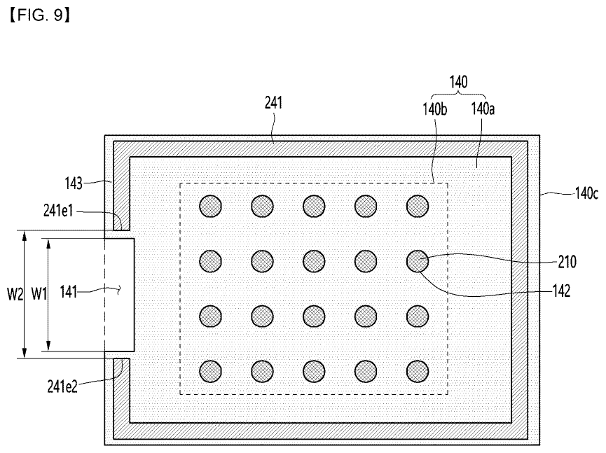

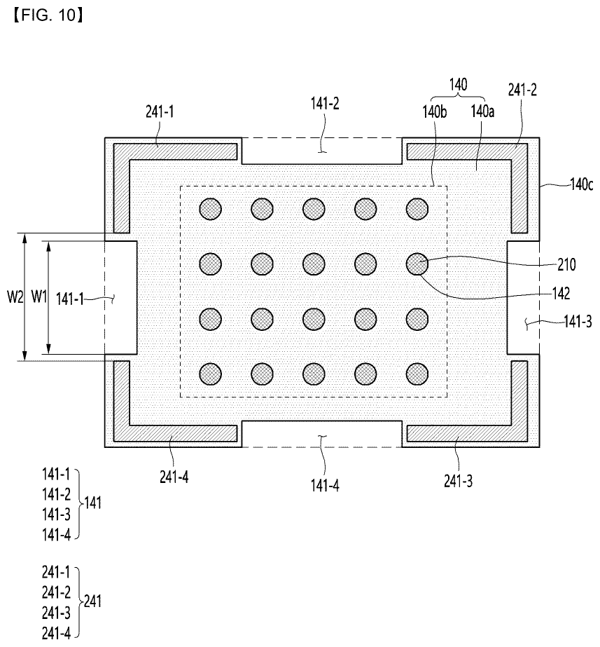

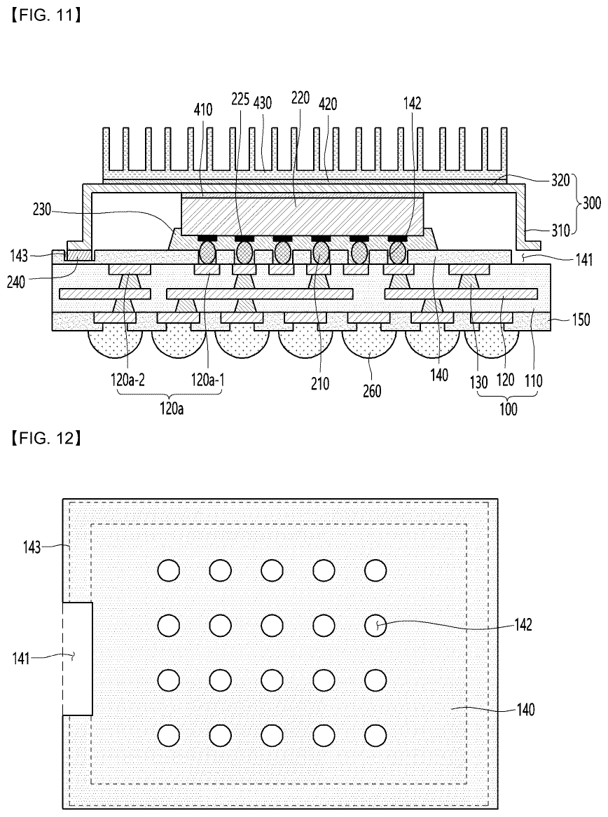

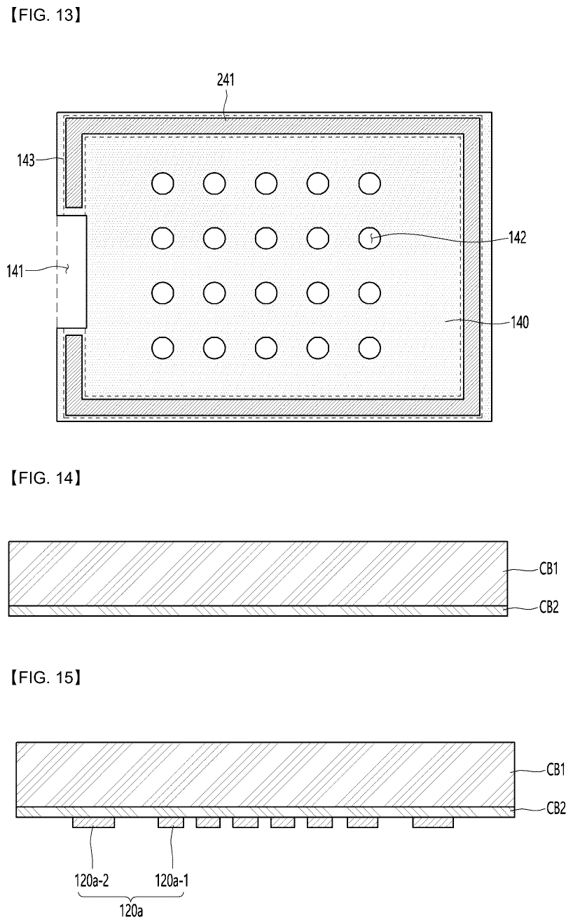

FIG. 11 is a cross-sectional view showing a semiconductor package according to a fifth embodiment, FIG. 12 is a plan view showing a first protective layer of a semiconductor package of FIG. 11, and FIG. 13 is a drawing showing a state in which a first adhesive member is disposed on a first protective layer of FIG. 12.

Referring to FIGS. 11 to 13, the semiconductor package may be different from the semiconductor package of the first embodiment in that a recess 143 is provided in the first protective layer 140 of the substrate 100. Therefore, only a structure of the recess 143 of the first protective layer 140 will be described below.

The first protective layer 140 may include a recess 143 provided in the circumferential region 140a. The recess 143 may have a shape concave from the upper surface of the first protective layer 140 toward the lower surface. The recess 143 can be spaced apart from the circumference 140c of the upper plate portion 320 of the first protective layer 140.

In addition, the recess 143 can be connected to the first opening 141 of the first protective layer 140. Through this, the embodiment allows the first adhesive member 240 to be disposed in the recess 143 while allowing the gas to be discharged through the first opening 141.

In addition, the embodiment can reduce the thickness of the semiconductor package by the depth of the above recess 143. Accordingly, the embodiment can miniaturize the semiconductor package.

The semiconductor package of the embodiment includes a substrate and a protective layer disposed on the substrate. In addition, the protective layer includes a first opening provided in a circumferential region of an upper surface of the protective layer and passing through the upper surface and the lower surface of the protective layer. In addition, the semiconductor package includes a first adhesive member disposed in the circumferential region of the upper surface of the protective layer and a cover member disposed on the first adhesive member.

At this time, the first adhesive member may be partially disposed in the circumferential region of the protective layer. Specifically, the first adhesive member may have an open loop shape along a circumferential direction of the upper surface of the protective layer.

Accordingly, the circumferential region includes a disposition region where the first adhesive member is disposed and a non-disposition region where the first adhesive member is not disposed. At this time, the non-disposition region vertically overlaps the first opening.

In other words, a lower surface of the cover member includes a first lower surface that contacts the first adhesive member and a second lower surface that does not contact the first adhesive member. In addition, the first opening vertically overlaps with the second lower surface of the cover member, but does not vertically overlap with the first adhesive member.

Accordingly, the embodiment can utilize not only the non-disposition region of the first adhesive member, but also a first opening of the protective layer connected to the non-disposition region as a vent hole. Therefore, the embodiment can easily discharge gas existing in a cavity space defined as an inner space of the cover member to an outside. Accordingly, the embodiment can solve physical reliability problems and electrical reliability problems caused by a presence of the gas in the cavity space. Therefore, the embodiment can further improve the product reliability of the semiconductor package.

Meanwhile, the protective layer of the embodiment includes a recess provided in a region where the first adhesive member is to be disposed while being connected to the first opening. In addition, the first adhesive member can be disposed in the recess. Through this, the embodiment can lower a height of the semiconductor package by a depth of the recess. Therefore, the embodiment can miniaturize the semiconductor package.

In addition, the embodiment allows a width of the non-disposition region of the first adhesive member to be greater than a width of the first opening. At this time, each of the width of the first opening and the width of the non-disposition region each mean a width in the circumferential direction of the upper surface of the protective layer. Accordingly, the embodiment can prevent the first adhesive member from overflowing into the first opening. Accordingly, the embodiment can further improve the product reliability of the semiconductor package. Furthermore, the embodiment provides a step between the non-disposition region and the first opening so that the gas generated in the cavity space can flow in a direction toward the first opening. Accordingly, the embodiment can further improve discharge characteristics of the gas.

FIGS. 14 to 23 are cross-sectional views for explaining a method for manufacturing a semiconductor package according to an embodiment in order of processes.

Hereinafter, a method for manufacturing a semiconductor package of FIG. 1 will be explained in the order of processes with reference to FIGS. 14 to 23. Meanwhile, the semiconductor packages of the second to fifth embodiments may also be manufactured based on the manufacturing processes described below.

Referring to FIG. 14, the embodiment prepares a material that serves as the basis for manufacturing a substrate 100. For example, the embodiment prepares a carrier board for manufacturing a substrate 100 of an ETS structure. The carrier board includes a carrier insulating layer CB1 and a carrier metal layer CB2 disposed on at least one surface of the carrier insulating layer CB1. Although FIG. 14 illustrates that the carrier metal layer CB2 is disposed only on the lower surface of the carrier insulating layer CB1, the embodiment is not limited thereto. For example, the carrier metal layer CB2 may also be disposed on the upper surface of the carrier insulating layer CB1. Accordingly, the embodiment may perform a process of manufacturing a plurality of substrates 100 simultaneously by using the carrier metal layers CB2 disposed on each side of the carrier insulating layer CB1.

Next, referring to FIG. 15, the embodiment forms a part of the electrode layer 120 of the substrate 100 on the lower surface of the carrier metal layer CB2 using the carrier metal layer CB2 disposed on at least one surface of the carrier insulating layer CB1 as a seed layer. For example, the embodiment performs a process of forming a first electrode layer 120a, which is an electrode layer disposed on an uppermost side of the substrate 100, on the lower surface of the carrier metal layer CB2. At this time, the first electrode layer 120a may include a first electrode pattern 120a-1 and a second electrode pattern 120a-2.

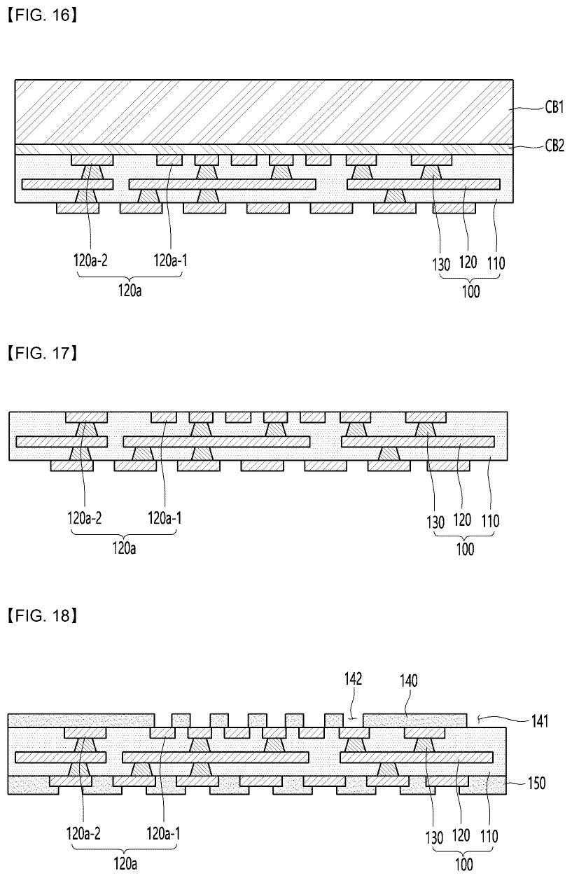

Next, referring to FIG. 16, in an embodiment, when the first electrode layer 120a is formed, a process of laminating an insulating layer 110, a process of forming a through hole, a process of forming a through electrode, and a process of forming an electrode layer are performed at least once to form a substrate 100.

Next, referring to FIG. 17, the embodiment can perform a process of removing the carrier board. For example, the embodiment can perform a process of separating the carrier insulating layer CB1 and the carrier metal layer CB2. Next, the embodiment can perform a process of removing the carrier metal layer CB2 disposed on the substrate 100 by etching.

Next, referring to FIG. 18, the embodiment can perform a process of forming the first protective layer 140 on the substrate 100.

To this end, the embodiment may perform a process of forming a first opening 141 and a second opening 142 of the first protective layer 140 by applying an insulating material that covers the entire upper portion of the substrate 100 and removing the applied insulating material through exposure and development. The first opening 141 may be formed in a circumferential region 140a of the first protective layer 140, and the second opening 142 may be formed in an inner region 140b of the first protective layer 140.

In response to this, the embodiment may perform a process of forming a second protective layer 150 on the lower portion of the substrate 100.

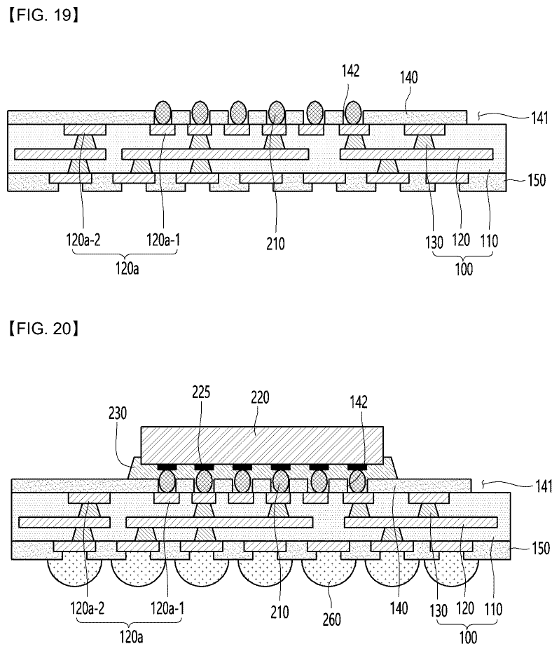

Next, referring to FIG. 19, the embodiment may perform a process of disposing a first connection part 210 on a first electrode pattern 120a-1 exposed through the second opening 142 of the first protective layer 140.

Next, referring to FIG. 20, the embodiment may perform a process of mounting a semiconductor device 220 on the first connection part 210. The terminal 225 of the semiconductor device 220 may be electrically connected to the first electrode pattern 120a-1 through the first connection part 210. Thereafter, the embodiment may perform a process of forming a molding member 230 that molds the semiconductor device 220 and the first connection part 210.

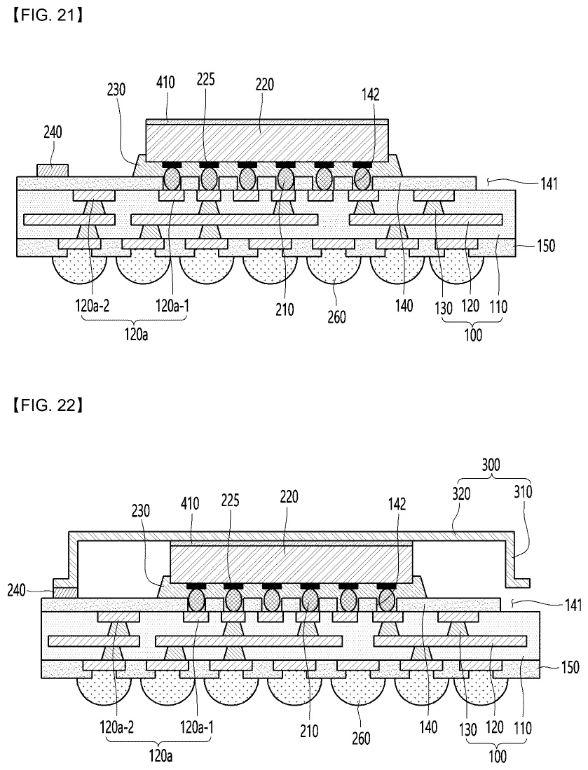

Next, referring to FIG. 21, the embodiment may proceed with a process of applying a first adhesive member 240 in the circumferential region of the upper surface of the first protective layer 140. At this time, the first adhesive member 240 is disposed in an open loop shape along the circumferential direction of the upper surface of the first protective layer 140. For example, the circumferential region 140a of the first protective layer 140 includes a non-disposition region where the first adhesive member 240 is not disposed. The non-disposition region may be a separation region where one end and the other end of the first adhesive member 240 are separated. In addition, the non-disposition region may vertically overlap with the first opening 141 provided in the first protective layer 140. Next, the embodiment may proceed with a process of applying a second adhesive member 410 to the upper surface of the semiconductor device 220.

Next, referring to FIG. 22, the embodiment can perform a process of attaching a cover member 300 on the substrate 100 using the first adhesive member 240 and the second adhesive member 410. Then, a heat process of curing the first adhesive member 240 can be performed after the cover member 300 is attached. At this time, gas can be generated during the heat process, and the generated gas can be discharged to the outside of the cover member 300 through the non-disposition region of the first adhesive member 240 and the first opening 141 of the first protective layer 140.

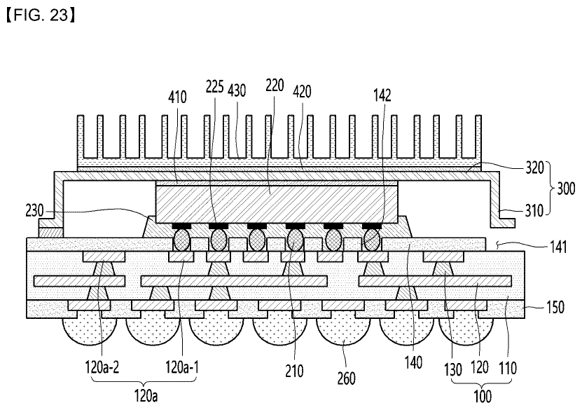

Next, referring to FIG. 23, the embodiment can perform a process of applying a third adhesive member 420 to the upper surface of the upper plate portion 320 of the cover member 300. Thereafter, the embodiment can proceed with a process of attaching a heat dissipation plate 430 on the third adhesive member 420.

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A semiconductor package comprising:
a substrate;
a protective layer disposed on the substrate;
a first adhesive member disposed on the protective layer and having an open loop shape along a circumferential direction of an upper surface of the protective layer; and
a cover member disposed on the first adhesive member,
wherein a lower surface of the cover member includes:
a first lower surface that contacts the first adhesive member, and
a second lower surface that does not contact the first adhesive member, and
wherein the protective layer includes a first opening that vertically overlaps the second lower surface of the cover member and does not vertically overlap the first adhesive member.

2. The semiconductor package of claim 1, wherein at least a portion of the second lower surface of the cover member does not vertically overlap the first opening.

3. The semiconductor package of claim 1, wherein an upper surface of the protective layer includes a circumferential region adjacent to a circumference of the upper surface of the protective layer, and
wherein the first adhesive member is partially disposed in the circumferential region along the circumferential direction.

4. The semiconductor package of claim 3, wherein the first opening vertically overlaps a region of the circumferential region in which the first adhesive member is not disposed.

5. The semiconductor package of claim 4, wherein a width in the circumferential direction of the region in which the first adhesive member is not disposed is larger than a width in the circumferential direction of the first opening.

6. The semiconductor package of claim 3, wherein a plurality of first openings are provided to be spaced apart from each other along the circumferential direction, and
wherein the first adhesive member includes a plurality of first adhesive patterns disposed along the circumferential direction between the plurality of first openings.

7. The semiconductor package of claim 3, wherein the first opening is connected to an outer side surface of the protective layer.

8. The semiconductor package of claim 7, wherein the protective layer includes a recess concave from an upper surface of the protective layer toward a lower surface of the protective layer and vertically overlapping the first adhesive member, and
wherein the first adhesive member is disposed in the recess.

9. The semiconductor package of claim 8, wherein the recess is spaced apart from the outer side surface of the protective layer and connected to the first opening.

10. The semiconductor package of claim 3, wherein the substrate includes:
an insulating structure comprising a plurality of insulating layers laminated along a vertical direction; and
a first electrode layer disposed on the insulating structure, and
wherein the protective layer includes a second opening passing through upper and lower surfaces of the protective layer and vertically overlapping the first electrode layer.

11. The semiconductor package of claim 10, wherein the first opening does not vertically overlap with the first electrode layer.

12. The semiconductor package of claim 10, further comprising:
a first connection part disposed on the first electrode layer vertically overlapping with the second opening; and
a semiconductor device disposed on the first connection part.

13. The semiconductor package of claim 12, wherein the cover member includes:
a side plate portion separated from the semiconductor device and covering a side region of the semiconductor device; and
an upper plate portion extended from the side plate portion and covering an upper region of the semiconductor device, and
wherein a lower surface of the cover member is a lower surface of the side plate portion.

14. The semiconductor package of claim 13, further comprising:
a second adhesive member disposed between an upper surface of the semiconductor device and a lower surface of the upper plate portion.

15. The semiconductor package of claim 14, further comprising:
a third adhesive member disposed on an upper surface of the upper plate portion; and
a heat dissipation plate disposed on the third adhesive member.

16. The semiconductor package of claim 12, further comprising:
a molding member disposed on the substrate and molding the first connection portion and a side surface of the semiconductor device.

17. The semiconductor package of claim 1, wherein the protective includes a solder resist.
